(19) United States
(12) Patent Application Publication
(10) Pub. No.: US 2022/0116014 A1
(43) Pub. Date: Apr. 14, 2022

(54) SURFACE ACOUSTIC WAVE (SAW) DEVICE WITH HIGH PERMITTIVITY DIELECTRIC FOR INTERMODULATION DISTORTION IMPROVEMENT

(71) Applicant: RF360 EUROPE GMBH, Munchen (DE)

(72) Inventor: Cedric Olivier Gerald POIREL, Singapore (SG)

(21) Appl. No.: 17/069,602

(22) Filed: Oct. 13, 2020

(51) Int. Cl. H03H 9/02; H03H 3/08; H03H 9/145; H03H 9/25; H03H 9/64

(52) U.S. Cl. CPC H03H 9/02944; H03H 3/08; H03H 9/6483; H03H 9/25; H03H 9/145

(57) ABSTRACT

Certain aspects of the present disclosure provide a surface acoustic wave (SAW) device and methods for fabricating such a SAW device. One example SAW device generally includes a piezoelectric substrate, an interdigital transducer (IDT) disposed above the piezoelectric substrate, and a plurality of first regions of dielectric material. The IDT comprises a first electrode having a first plurality of fingers and a second electrode having a second plurality of fingers interdigitated with the first plurality of fingers of the first electrode. The plurality of first regions are disposed above the piezoelectric substrate and between the first and second pluralities of fingers of the IDT, and the dielectric material has a relative permittivity greater than 3.9.

### TECHNICAL FIELD

Certain aspects of the present disclosure relate generally to electronic components and, more particularly, to surface acoustic wave (SAW) devices implemented with high-permittivity dielectric elements.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric, material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as cellular phones).

Today, surface acoustic wave (SAW) or bulk acoustic wave (BAW) components may be used in wireless communication devices, such as for implementing RF filters. In SAW technology, the acoustic wave propagates laterally on a surface of a piezoelectric substrate, with the movement of the piezoelectric generated by metal interdigitated transducers (IDTs) on the surface. The wavelength of the acoustic wave may be defined by the pitch (e.g., the width of the metal finger and gap) of the IDT. In BAW technology, the acoustic wave propagates vertically through a three-dimensional structure, with an electric field applied through electrodes above and below a piezoelectric material. The wavelength, in this case, is defined by the thickness of the piezoelectric material.

In one type of SAW device, a surface acoustic wave is generated by an input IDT and detected by an output IDT. In another type of SAW device, the acoustic energy may be confined using reflectors on either side of the IDT. A planar resonant cavity created between two mirrors consisting of reflecting metal strips can also be used to trap the acoustic energy.

As the number of frequency bands used in wireless communications increases and as the desired frequency band of filters widen, the performance of acoustic filters increases in importance to reduce losses and increase overall performance of electronic devices. Acoustic filters with improved performance, particularly filters with reduced intermodulation distortion, are therefore sought after.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include implementation of high-permittivity dielectric materials in surface acoustic wave (SAW) technology to, for example, reduce intermodulation distortion (IMD).

Certain aspects of the present disclosure provide a SAW device. The SAW device generally includes a piezoelectric substrate, an interdigital transducer (IDT) disposed above the piezoelectric substrate, and a plurality of first regions of dielectric material. The IDT includes a first electrode having a first plurality of fingers and a second electrode having a second plurality of fingers interdigitated with the first plurality of fingers of the first electrode. The plurality of first regions is disposed above the piezoelectric substrate and between the first and second pluralities of fingers of the IDT, and the dielectric material has a relative permittivity greater than 3.9.

Certain aspects of the present disclosure provide a wireless device. The wireless device generally includes a radio frequency (RF) circuit and a SAW filter coupled to the RF circuit. The SAW filter generally includes a piezoelectric substrate, an interdigital transducer (IDT) disposed above the piezoelectric substrate, and a plurality of regions of dielectric material. The IDT includes a first electrode having a first plurality of fingers and a second electrode having a second plurality of fingers interdigitated with the first plurality of fingers of the first electrode. The plurality of regions is disposed above the piezoelectric substrate and between the first and second pluralities of fingers of the IDT, and the dielectric material has a relative permittivity greater than 3.9.

Certain aspects of the present disclosure generally relate to a method for fabricating a SAW device. The method generally includes forming an IDT above a piezoelectric substrate, the IDT comprising a first electrode having a first plurality of fingers and a second electrode having a second plurality of fingers interdigitated with the first plurality of fingers of the first electrode. The method further includes forming a plurality of regions of dielectric material above the piezoelectric substrate and between the first and second pluralities of fingers of the IDT, the dielectric material of the plurality of regions having a relative permittivity greater than 3.9.

Certain aspects of the present disclosure are directed to a SAW device. The SAW device generally includes a piezoelectric substrate, a dielectric layer disposed above the piezoelectric substrate, and an IDT disposed above the dielectric layer. The dielectric layer primarily comprises a different material than the piezoelectric substrate. The IDT is generally composed of a first electrode having a first plurality of fingers and a second electrode having a second plurality of fingers interdigitated with the first plurality of fingers of the first electrode.

Certain aspects of the present disclosure are directed to a plurality of resonators forming a filter circuit. In this case, the SAW device described herein may be a resonator in the plurality of resonators.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1A is a diagram of a perspective view of an example electroacoustic device, in which certain aspects of the present disclosure may be practiced.

FIG. 1B is a diagram of a side view of the example electroacoustic device of FIG. 1A.

FIG. 2A is a top view of an example electrode structure of an electroacoustic device, in which certain aspects of the present disclosure may be practiced.

FIG. 2B is a top view of another example electrode structure of an electroacoustic device, in which certain aspects of the present disclosure may be practiced.

FIG. 3 is a cross-sectional view of an example electroacoustic device with a continuous thin layer of a dielectric material deposited on a piezoelectric substrate prior to electrode deposition, in accordance with certain aspects of the present disclosure.

FIG. 4A is a cross-sectional view of an example electroacoustic device with a high-permittivity dielectric material deposited between electrodes, in accordance with certain aspects of the present disclosure.

FIG. 4B is a cross-sectional view of an example electroacoustic device with a high-permittivity dielectric material deposited between electrodes and a continuous thin layer of dielectric material, in accordance with certain aspects of the present disclosure.

FIG. 5 is a flow diagram of example operations for forming an example SAW device, in accordance with certain aspects of the present disclosure.

FIG. 6 is a schematic diagram of an electroacoustic filter circuit that may include the example electroacoustic device of FIG. 3, FIG. 4A, or FIG. 4B.

FIG. 7 is a functional block diagram of at least a portion of an example simplified wireless transceiver circuit in which the filter circuit of FIG. 6 may be employed.

FIG. 8 is a diagram of an environment that includes an electronic device that includes a wireless transceiver such as the transceiver circuit of FIG. 7.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to a surface acoustic wave (SAW) device with a dielectric material having a relatively high permittivity (e.g., a relative permittivity (εᵣ)>3.9, and in some cases, εᵣ>9.3) disposed between the fingers of an interdigital transducer (IDT). The high-permittivity dielectric regions may reduce leakage current between the fingers of the IDT, thereby reducing intermodulation distortion (IMD) and improving linearity for the SAW device.

The detailed description set forth below in connection with the appended drawings is intended as a description of exemplary implementations and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

### Example Electroacoustic Devices

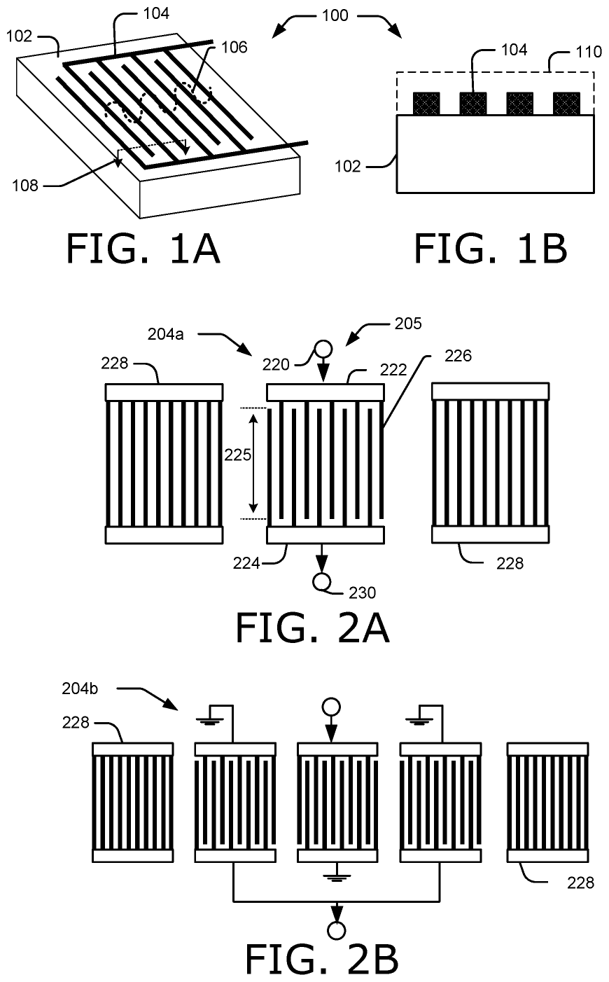

FIG. 1A is a diagram of a perspective view of an example electroacoustic device 100. The electroacoustic device 100 may be configured as or be a portion of a SAW resonator. In certain descriptions herein, the electroacoustic device 100 may be referred to as a SAW resonator. However, there may be other electroacoustic device types that may be constructed based on the principles described herein.

The electroacoustic device 100 includes an electrode structure 104, that may be referred to as an interdigital transducer (IDT), on the surface of a piezoelectric material 102. The electrode structure 104 generally includes first and second comb-shaped electrode structures (conductive and generally metallic) with electrode fingers extending from two busbars towards each other arranged in an interlocking manner in between the two busbars (e.g., arranged in an interdigitated manner). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a diagram of a side view of the electroacoustic device 100 of FIG. 1A along a cross-section 108 shown in FIG. 1A. The electroacoustic device 100 is illustrated by a simplified layer stack including the piezoelectric material 102 with the electrode structure 104 disposed on the piezoelectric material 102. The electrode structure 104 is electrically conductive and generally formed from metallic materials. The electrode structure 104 may alternatively be formed from materials that are electrically conductive, but non-metallic (e.g., graphene). The piezoelectric material 102 may be formed from a variety of materials such as quartz, lithium tantalate (LiTaO₃), lithium niobite (LiNbO₃), doped variants of these, other piezoelectric materials, or other crystals. It should be appreciated that more complicated layer stacks including layers of various materials may be possible within the stack. For example, optionally, a temperature compensation layer 110 denoted by the dashed lines may be disposed above the electrode structure 104. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

FIG. 2A is a top view of an example electrode structure 204a of an electroacoustic device. The electrode structure 204a has an IDT 205 that includes a first busbar 222 (e.g., first conductive segment or rail) electrically connected to a first terminal 220 and a second busbar 224 (e.g., second conductive segment or rail) spaced from the first busbar 222 and connected to a second terminal 230. A plurality of conductive fingers 226 are connected to either the first busbar 222 or the second busbar 224 in an interdigitated manner. Fingers 226 connected to the first busbar 222 extend towards the second busbar 224 but do not connect to the second busbar 224 so that there is a small gap between the ends of these fingers 226 and the second busbar 224. Likewise, fingers 226 connected to the second busbar 224 extend towards the first busbar 222 but do not connect to the first busbar 222 so that there is a small gap between the ends of these fingers 226 and the first busbar 222. Similarly, small gaps may also be formed between fingers 226 and any structure extending from the first busbar 222 or the second busbar 224 (e.g., stub fingers).

Between the busbars, there is an overlap region including a central region where a portion of one finger overlaps with a portion of an adjacent finger as illustrated by the central region 225. This central region 225 including the overlap may be referred to as the aperture, track, or active region where electric fields are produced between the fingers 226 to cause an acoustic wave to propagate in this region of the piezoelectric material 102. The periodicity of the fingers 226 is referred to as the pitch of the IDT. The pitch may be indicated in various ways. For example, in certain aspects, the pitch may correspond to a magnitude of a distance between fingers in the central region 225. This distance may be defined, for example, as the distance between center points of each of the fingers (and may be generally measured between a right (or left) edge of one finger and the right (or left) edge of an adjacent finger when the fingers have uniform width). In certain aspects, an average of distances between adjacent fingers may be used for the pitch. The frequency at which the piezoelectric material vibrates is a main resonance frequency of the electrode structure 204a. This frequency is determined at least in part by the pitch of the IDT 205 and other properties of the electroacoustic device 100.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the converted electrical signal may be provided as an output, such as to one of the first terminal 220 or the second terminal 230, while the other terminal may function as an input.

A variety of electrode structures are possible. FIG. 2A may generally illustrate a one-port configuration. Other configurations (e.g., two-port configurations) are also possible. For example, the electrode structure 204a may have an input IDT 205 where each terminal 220 and 230 functions as an input. In this event, an adjacent output IDT (not illustrated) that is positioned between the reflectors 228 and adjacent to the input IDT 205 may be provided to convert the acoustic wave propagating in the piezoelectric material 102 to an electrical signal to be provided at output terminals of the output IDT.

FIG. 2B is a top view of another example electrode structure 204b of an electroacoustic device. In this case, a dual-mode SAW (DMS) electrode structure 204b is illustrated, the DMS structure being a structure that may induce multiple resonances. The electrode structure 204b includes multiple IDTs arranged between reflectors 228 and connected as illustrated. The electrode structure 204b is provided to illustrate the variety of electrode structures that principles described herein may be applied to including the electrode structures 204a and 204b of FIGS. 2A and 2B.

It should be appreciated that while a certain number of fingers 226 are illustrated, the number of actual fingers and length(s) and width(s) of the fingers 226 and busbars may be different in an actual implementation. Such parameters depend on the particular application and desired filter characteristics. In addition, a SAW filter may include multiple interconnected electrode structures each including multiple IDTs to achieve a desired passband (e.g., multiple interconnected resonators or IDTs to form a desired filter transfer function).

Electroacoustic devices such as SAW resonators are being designed to cover more frequency ranges (e.g., 500 MHz to 6 GHz), to have higher bandwidths (e.g., up to 20%), and to have improved efficiency and performance. In general, SAW resonators are subject to nonlinearities that give rise to intermodulation distortion (IMD). For example, slight conductivity through the air or dielectric between the IDT electrodes can cause arcing and can worsen the nonlinearity, power durability, and compression of the device. Cascading the acoustic track can reduce certain amounts of intermodulation distortion, but this technique occupies increased space to implement and leads to larger SAW devices.

Notably, the relative permittivity (εᵣ) of the piezoelectric substrate influences the intermodulation (nonlinearity) characteristic of a SAW filter. Nonlinear Mason equivalent circuit models have been used to simulate the effects that substrate permittivity can have on the nonlinearity of SAW filters. Furthermore, the relative permittivity of the material separating the electrodes that form IDTs on a SAW device likewise influences the nonlinearity behavior of the device. By adjusting the relative permittivity of certain dielectric structures in a SAW device, intermodulation distortion of the device can be reduced.

### Example Electroacoustic Device with Continuous Thin Dielectric Layer

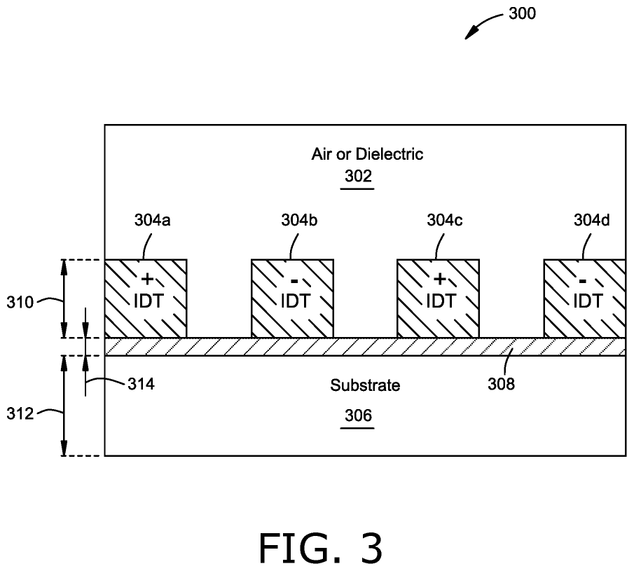

FIG. 3 is a cross-sectional view of an example electroacoustic device 300. The electroacoustic device 300 includes an IDT comprising a first electrode having a first plurality of fingers 304a and 304c, and a second electrode having a second plurality of fingers 304b and 304d that are interdigitated with the first plurality of fingers 304a and 304c of the first electrode. As shown, the plurality of fingers 304a and 304c of the first electrode have polarity opposite that of the plurality of fingers 304b and 304d of the second electrode. The plurality of fingers 304a-d of the IDT have a height 310, which may be between 80 nm to 500 nm, for example. Although only four fingers 304a-d are shown in FIG. 3 to illustrate the concept, it is to be understood that the IDT may include more or less than four fingers.

A material 302 may be disposed above and between the fingers 304a-d of the IDT. The material 302 may be air, for example, when the electroacoustic device 300 is a standard SAW device. Alternatively, the material 302 may be a dielectric material such as silicon dioxide (SiO₂) if the electroacoustic device 300 is a temperature-compensated surface acoustic wave (TCSAW) device. The material 302 may have a low relative permittivity (e.g., εᵣ=1 for air and εᵣ=3.9 for SiO₂).

The electroacoustic device 300 (e.g., that may be configured as or be a part of a SAW resonator) is similar to the electroacoustic device 100 of FIG. 1A, but has a different layer stack. In particular, the electroacoustic device 300 includes a continuous thin dielectric layer 308 that is provided on (or at least above) a piezoelectric substrate 306 having a height 312. The piezoelectric substrate 306, for example, may comprise lithium tantalate (LiTaO₃), lithium niobite (LiNbO₃), some doped variant thereof, or any other suitable material. The piezoelectric substrate 306 may also include other layers.

As shown in FIG. 3, the dielectric layer 308 has a height 314, which may also be referred to as a thickness. It may be desirable to deposit the dielectric layer 308 in a very thin layer to avoid loss of coupling between the piezoelectric substrate 306 and the fingers 304a-d of the electrodes. For example, the height 314 of the continuous dielectric layer 308 may be 2.5 nm. In general, the piezoelectric substrate 306 may be substantially thicker than the dielectric layer 308 (e.g., potentially on the order of 20,000 to 200,000 times thicker as one example, or more). Additionally, the IDT electrode fingers 304a-d may be substantially thicker than the dielectric layer 308 (e.g., potentially on the order of up to 20 times thicker as one example). Stated another way, height 310 and height 312 may be substantially greater than height 314, by at least an order of magnitude.

Intermodulation improvement has been observed in devices that include a thin dielectric layer, such as dielectric layer 308, composed of a dielectric material that has a high relative permittivity. Accordingly, in certain aspects of the present disclosure, the dielectric layer 308 comprises aluminum oxide (Al₂O₃), also referred to as alumina, having a relative permittivity range of 9.3-11.5. In certain other aspects, the dielectric layer 308 may comprise any dielectric material that has a relative permittivity greater than 3.9.

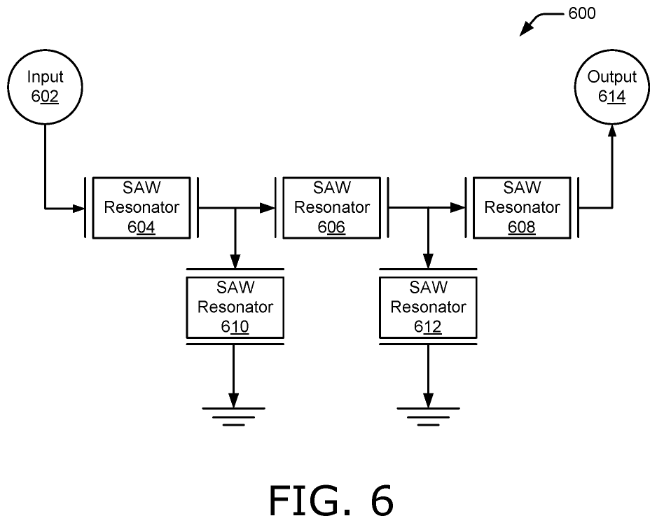

According to certain aspects of the present disclosure, the electroacoustic device 300 may be implemented in a filter or duplexer of a radio frequency (RF) circuit for use in a wireless communications device. Such a wireless communications device is described in further detail in the description of FIGS. 6-8.

### Example Electroacoustic Device with a Structured, High Permittivity Dielectric Layer Deposited Between Electrodes

As explained above, it may be desirable in some applications to have a continuous thin layer of high-permittivity dielectric deposited above the piezoelectric substrate. In other applications, depositing structured, high-permittivity dielectric regions between the electrodes of an IDT may offer lower intermodulation distortion in SAW devices. The structured, high-permittivity dielectric regions may be discontinuous, thereby increasing the thickness of the dielectric region while reducing any impact on the electromechanical coupling between the IDT electrodes and the piezoelectric substrate.

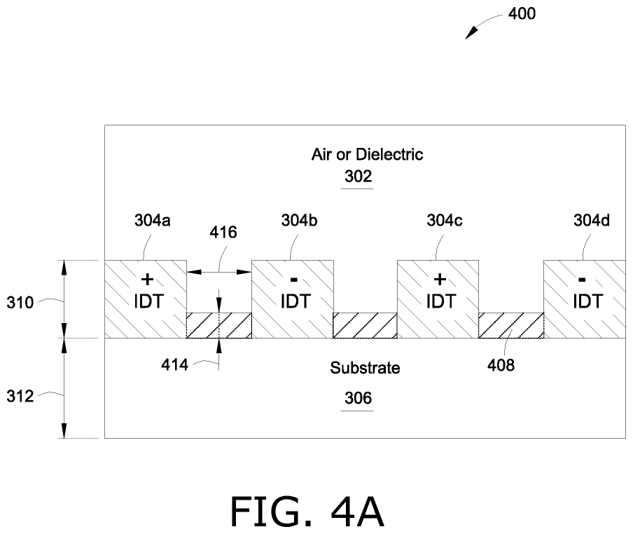

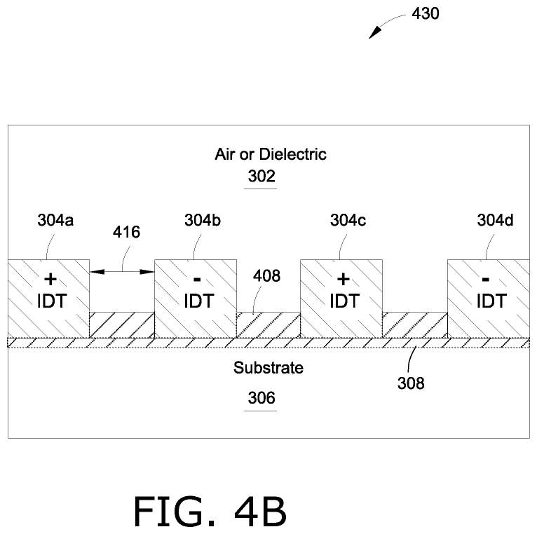

FIG. 4A is a cross-sectional view of an example electroacoustic device 400, in accordance with certain aspects of the present disclosure. The electroacoustic device 400 may be configured as or be a part of a SAW resonator. As shown, the electroacoustic device 400 may include a plurality of dielectric regions 408 disposed above the piezoelectric substrate 306 and between the first and second pluralities of fingers 304a-d of the IDT. In certain aspects, the plurality of dielectric regions 408 may have a relative permittivity greater than 3.9. In certain other aspects, it may be beneficial for the dielectric regions 408 to have a relative permittivity of at least 9.3.

The dielectric regions 408 may serve as a high-permittivity dielectric region between the electrode fingers 304a-d to increase permittivity and reduce leakage current between the electrodes. As a result, intermodulation distortion in the electroacoustic device 400 may be reduced. The dielectric regions 408 may have a height 414, which may be selected based on several factors including, but not limited to, the SAW frequency, the distance 416 between electrode fingers 304a-d (or the pitch as described above), the quality factor (Q), the coupling, and/or the height 310 of the electrode fingers 304a-d. For certain aspects, the dielectric regions 408 may have uniform height, whereas in other aspects, the dielectric regions may have two or more different heights.

Table 1 provides a non-exhaustive list of materials that may be suitable to use for the dielectric regions 408. Table 1 also includes the relative permittivity for each of the listed materials.

TABLE 1

| Material | Relative Permittivity |
|---|---|
| Aluminum Oxide (Al₂O₃) | 9.3-11.5 |
| Zirconium Dioxide (ZrO₂) | 12-25 |
| Hafnium Dioxide (HfO₂) | 30 |
| Hafnium Silicate (HfSiOₓ) | 30 |
| Tantalum Pentoxide (Ta₂O₅) | 25-65 |

According to certain aspects of the present disclosure, the height 414 of at least one of the plurality of dielectric regions 408 may be less than 50% of the height 310 of the first and second pluralities of fingers of the IDT. In certain aspects, the height 414 of at least one of the plurality of dielectric regions 408 may be at least 5% of the height 310 of at least one of the first or the second pluralities of fingers 304a-d of the IDT. For example, the height 414 of the plurality of dielectric regions 408 may be at least 5 nm for a finger height of 100 nm.

According to certain aspects of the present disclosure, the electroacoustic device 400 may further include one or more additional regions of dielectric material or air. For example, the one or more additional regions may be the material 302 described above with respect to FIG. 3. The one or more additional regions may be disposed above the plurality of dielectric regions 408, and the one or more additional regions may extend above the first and second pluralities of fingers 304a-d of the IDT (as illustrated for the material 302 in FIG. 3). The dielectric material of the additional region(s) may be the same or different from the dielectric material of the plurality of dielectric regions 408. For example, the dielectric material of the additional region(s) may have lower relative permittivity than the dielectric material of the dielectric regions 408. The one or more additional regions may operate as a temperature compensation layer, and in this case, the dielectric material of the additional region(s) may be SiO₂, for example.

According to certain aspects of the present disclosure, the electroacoustic device 400 may be implemented in a filter or duplexer of a RF circuit for use in a wireless communications device. Such a wireless communications device is described in further detail in the description of FIGS. 6-8.

According to certain aspects of the present disclosure, the electroacoustic device 400 may further include a second layer that is provided on (or at least above) the piezoelectric substrate 306. For example, as illustrated in the electroacoustic device 430 of FIG. 4B, the second layer may be the dielectric layer 308 described with respect to FIG. 3. The second layer may be deposited as a thin layer to avoid loss of coupling between the piezoelectric substrate 306 and the first and second pluralities of fingers 304a-d of the IDT. The plurality of dielectric regions 408 may be disposed above the second layer, and between the first and second pluralities of fingers 304a-d of the IDT. The plurality of dielectric regions 408 may be thicker (i.e., have a greater height) than the second layer.

According to certain aspects, the dielectric regions 408 may be implemented in a thin-film SAW device, where the first and second pluralities of fingers 304a-d of the IDT and the dielectric regions 408 are disposed above a thin-film piezoelectric layer, as compared to the piezoelectric substrate 306. The thin-film piezoelectric layer may be disposed above a substrate, which may comprise a temperature compensation layer (e.g., composed of SiO₂), at least one charge trapping layer, and at least one substrate layer.

### Example Operations for Fabricating a SAW Device

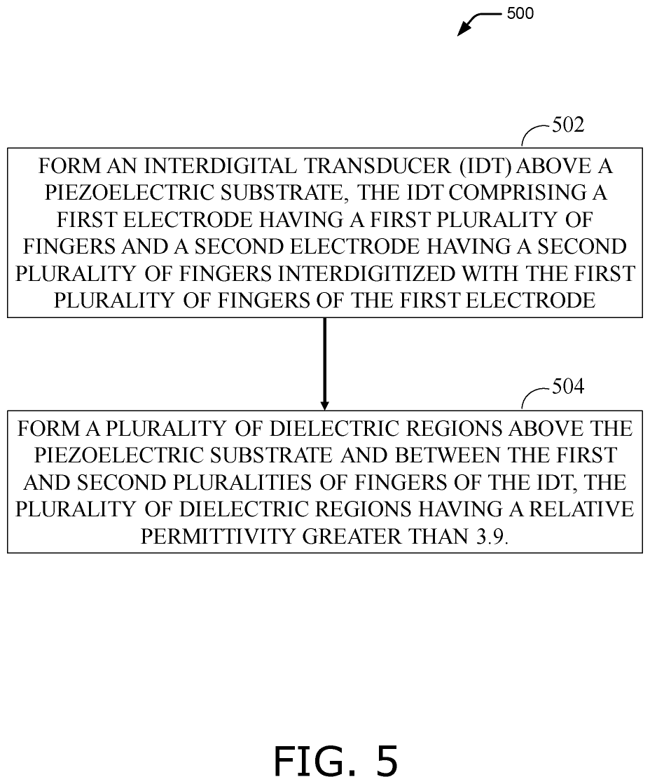

FIG. 5 is a block diagram of example operations 500 for fabricating a SAW device (e.g., the electroacoustic device 400 or 430 of FIG. 4A or 4B, respectively), in accordance with certain aspects of the present disclosure. The operations 500 are described in the form of a set of blocks that specify the operations that can be performed. However, operations are not necessarily limited to the order shown in FIG. 5 or described herein, for the operations may be implemented in alternative orders or in fully or partially overlapping manners. Also, more, fewer, and/or different operations may be implemented to perform the operations 500. The operations 500 may be performed by a semiconductor fabrication facility (e.g., a “fab house”).

The operations 500 may begin, at block 502, with the fabrication facility forming an IDT above a piezoelectric substrate. The formed IDT may include a first electrode having a first plurality of fingers and a second electrode having a second plurality of fingers interdigitated with the first plurality of fingers of the first electrode.

Referring to block 504, a plurality of dielectric regions is formed above the piezoelectric substrate and between the first and second pluralities of fingers of the IDT. The formed plurality of dielectric regions may have a relative permittivity greater than 3.9. For example, at least one of the plurality of dielectric regions may comprise aluminum oxide (Al₂O₃), hafnium dioxide (HfO₂), hafnium silicon oxide (HfSiO₂), zirconium dioxide (ZrO₂), or tantalum pentoxide (Ta₂O₅). According to certain aspects of the present disclosure, forming the plurality of dielectric regions at block 504 may involve performing atomic layer deposition (ALD) to deposit the plurality of dielectric regions above the piezoelectric substrate and between the first and second pluralities of fingers of the IDT.

### Example Integration into a Filter and Wireless Communications Device

FIG. 6 is a schematic diagram of an electroacoustic filter circuit 600 that may include the electroacoustic devices 300, 400 of FIGS. 3 and 4. The filter circuit 600 provides one example of where the disclosed SAW devices may be used. The filter circuit 600 includes an input terminal 602 and an output terminal 614. Between the input terminal 602 and the output terminal 614, a ladder-type network of SAW resonators is provided. The filter circuit 600 includes a first SAW resonator 604, a second SAW resonator 606, and a third SAW resonator 608 all electrically connected in series between the input terminal 602 and the output terminal 614. A fourth SAW resonator 610 (e.g., a shunt resonator) has a first terminal connected between the first SAW resonator 604 and the second SAW resonator 606 and has a second terminal connected to a reference potential node (e.g., electric ground) for the filter circuit 600. A fifth SAW resonator 612 (e.g., a shunt resonator) has a first terminal connected between the second SAW resonator 606 and the third SAW resonator 608 and has a second terminal connected to the reference potential node. The electroacoustic filter circuit 600 may, for example, be a bandpass filter circuit having a passband with a selected frequency range (e.g., on the order between 500 MHz and 6 GHz).

FIG. 7 is a functional block diagram of at least a portion of an example of a simplified wireless transceiver circuit 700 in which the filter circuit 600 of FIG. 6 may be employed. The transceiver circuit 700 is configured to receive signals/information for transmission (shown as in-phase (I) and quadrature (Q) values) which is provided to one or more baseband (BB) filters 712. The filtered output is provided to one or more mixers 714 for upconversion to radio frequency (RF) signals. The output from the one or more mixers 714 may be provided to a driver amplifier (DA) 716 whose output may be provided to a power amplifier (PA) 718 to produce an amplified signal for transmission. The amplified signal is output to the antenna 722 through one or more filters 720 (e.g., duplexers if used as a frequency division duplex transceiver or other filters). The one or more filters 720 may include the filter circuit 600 of FIG. 6.

The antenna 722 may be used for both wirelessly transmitting and receiving data. The transceiver circuit 700 includes a receive path through the one or more filters 720 to be provided to a low noise amplifier (LNA) 724 and a further filter 726 and then downconverted from the receive frequency to a baseband frequency through one or more mixer circuits 728 before the signal is further processed (e.g., provided to an analog-to-digital converter (ADC) and then demodulated or otherwise processed in the digital domain). There may be separate filters for the receive circuit (e.g., may have a separate antenna or have separate receive filters) that may be implemented using the filter circuit 600 of FIG. 6.

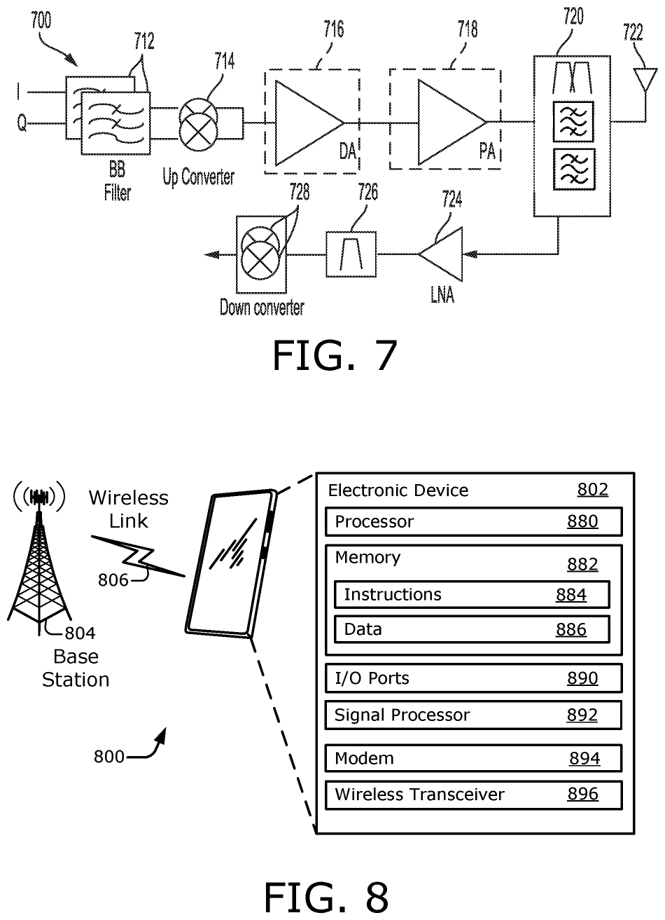

FIG. 8 is a diagram of an environment 800 that includes an electronic device 802, in which aspects of the present disclosure may be practiced. In the environment 800, the electronic device 802 communicates with a base station 804 through a wireless link 806. As shown, the electronic device 802 is depicted as a smart phone. However, the electronic device 802 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, and so forth.

The base station 804 communicates with the electronic device 802 via the wireless link 806, which may be implemented as any suitable type of wireless link. Although depicted as a base station tower of a cellular radio network, the base station 804 may represent or be implemented as another device, such as a satellite, terrestrial broadcast tower, access point, peer-to-peer device, mesh network node, fiber optic line, another electronic device generally as described above, and so forth. Hence, the electronic device 802 may communicate with the base station 804 or another device via a wired connection, a wireless connection, or a combination thereof. The wireless link 806 can include a downlink of data or control information communicated from the base station 804 to the electronic device 802 and an uplink of other data or control information communicated from the electronic device 802 to the base station 804. The wireless link 806 may be implemented using any suitable communication protocol or standard, such as 3rd Generation Partnership Project Long-Term Evolution (3GPP LTE), 3GPP NR 5G, IEEE 802.11, IEEE 802.16, Bluetooth™, and so forth.

The electronic device 802 includes a processor 880 and a memory 882. The memory 882 may be or form a portion of a computer-readable storage medium. The processor 880 may include any type of processor, such as an application processor or a multi-core processor, that is configured to execute processor-executable instructions (e.g., code) stored by the memory 882. The memory 882 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 882 is implemented to store instructions 884, data 886, and other information of the electronic device 802, and thus when configured as or part of a computer-readable storage medium, the memory 882 does not include transitory propagating signals or carrier waves.

The electronic device 802 may also include input/output ports 890. The I/O ports 890 enable data exchanges or interaction with other devices, networks, or users or between components of the device.

The electronic device 802 may further include a signal processor (SP) 892 (e.g., such as a digital signal processor (DSP)). The signal processor 892 may function similar to the processor and may be capable of executing instructions and/or processing information in conjunction with the memory 882.

For communication purposes, the electronic device 802 also includes a modem 894, a wireless transceiver 896, and an antenna (not shown). The wireless transceiver 896 provides connectivity to respective networks and other electronic devices connected therewith using radio-frequency (RF) wireless signals and may include the transceiver circuit 700 of FIG. 7. The wireless transceiver 896 may facilitate communication over any suitable type of wireless network, such as a wireless local area network (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

By way of example, an element, or any portion of an element, or any combination of elements described herein may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoCs), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuit.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. A surface acoustic wave (SAW) device comprising:
a piezoelectric substrate;
an interdigital transducer (IDT) disposed above the piezoelectric substrate and comprising a first electrode having a first plurality of fingers and a second electrode having a second plurality of fingers interdigitated with the first plurality of fingers of the first electrode; and
a plurality of first regions of dielectric material disposed above the piezoelectric substrate and between the first and second pluralities of fingers of the IDT, the dielectric material of the plurality of first regions having a relative permittivity greater than 3.9.

2. The SAW device of claim 1, wherein the dielectric material of at least one of the plurality of first regions comprises aluminum oxide (Al₂O₃).

3. The SAW device of claim 1, wherein the dielectric material of at least one of the plurality of first regions comprises hafnium dioxide (HfO₂) or hafnium silicon oxide (HfSiO₂).

4. The SAW device of claim 1, wherein the dielectric material of at least one of the plurality of first regions comprises zirconium dioxide (ZrO₂) or tantalum pentoxide (Ta₂O₅).

5. The SAW device of claim 1, wherein a height of the plurality of first regions is at least 5% of a height of at least one of the first or the second plurality of fingers of the IDT.

6. The SAW device of claim 1, wherein a height of at least one of the plurality of first regions is no more than 50% of a height of the first and the second pluralities of fingers of the IDT.

7. The SAW device of claim 1, wherein the relative permittivity of the dielectric material of the plurality of first regions is at least 9.3.

8. The SAW device of claim 1, further comprising one or more second regions of dielectric material disposed above the plurality of first regions and extending above the first and the second pluralities of fingers of the IDT.

9. The SAW device of claim 8, wherein the dielectric material of the one or more second regions has a different relative permittivity than the dielectric material of the plurality of first regions.

10. The SAW device of claim 1, further comprising one or more second regions disposed above the plurality of first regions and extending above the first and the second pluralities of fingers of the IDT, the one or more second regions comprising air.

11. A plurality of resonators forming a filter circuit, wherein the SAW device of claim 1 is a resonator in the plurality of resonators.

12. A wireless device comprising:
a radio frequency (RF) circuit; and
a surface acoustic wave (SAW) filter coupled to the RF circuit, the SAW filter comprising:
a piezoelectric substrate;
an interdigital transducer (IDT) disposed above the piezoelectric substrate and comprising a first electrode having a first plurality of fingers and a second electrode having a second plurality of fingers interdigitated with the first plurality of fingers of the first electrode; and
a plurality of regions of dielectric material disposed above the piezoelectric substrate and between the first and second pluralities of fingers of the IDT, the dielectric material of the plurality of regions having a relative permittivity greater than 3.9.

13. The wireless device of claim 12, wherein the dielectric material of at least one of the plurality of regions comprises hafnium dioxide (HfO₂), hafnium silicon oxide (HfSiO₂), zirconium dioxide (ZrO₂), or tantalum pentoxide (Ta₂O₅).

14. The wireless device of claim 12, wherein the dielectric material of at least one of the plurality of regions comprises aluminum oxide (Al₂O₃).

15. The wireless device of claim 12, wherein a height of the plurality of regions is at least 5% of a height of at least one of the first or the second plurality of fingers of the IDT.

16. The wireless device of claim 12, wherein a height of at least one of the plurality of regions is no more than 50% of a height of the first and the second pluralities of fingers of the IDT.

17. The wireless device of claim 12, wherein the relative permittivity of the dielectric material of the plurality of regions is at least 9.3.

18. A method of fabricating a surface acoustic wave (SAW) device, the method comprising:
forming an interdigital transducer (IDT) above a piezoelectric substrate, the IDT comprising a first electrode having a first plurality of fingers and a second electrode having a second plurality of fingers interdigitated with the first plurality of fingers of the first electrode; and
forming a plurality of regions of dielectric material above the piezoelectric substrate and between the first and second pluralities of fingers of the IDT, the dielectric material of the plurality of regions having a relative permittivity greater than 3.9.

19. The method of claim 18, wherein forming the plurality of regions comprises performing atomic layer deposition (ALD) to deposit the plurality of regions above the piezoelectric substrate and between the first and second pluralities of fingers of the IDT.

20. The method of claim 18, wherein the dielectric material of at least one of the plurality of regions comprises aluminum oxide (Al₂O₃).

21. The method of claim 18, wherein the dielectric material of at least one of the plurality of regions comprises hafnium dioxide (HfO₂), hafnium silicon oxide (HfSiO₂), zirconium dioxide (ZrO₂), or tantalum pentoxide (Ta₂O₅).

22. The method of claim 18, wherein a height of the plurality of regions is at least 5% of a height of at least one of the first or the second plurality of fingers of the IDT.

23. The method of claim 18, wherein a height of at least one of the plurality of regions is no more than 50% of a height of the first and the second pluralities of fingers of the IDT.

24. The method of claim 18, wherein the relative permittivity of the dielectric material of the plurality of regions is at least 9.3.

25. A surface acoustic wave (SAW) device comprising:
a piezoelectric substrate;
a dielectric layer disposed above the piezoelectric substrate and primarily comprising a different material than the piezoelectric substrate; and
an interdigital transducer (IDT) disposed above the dielectric layer and comprising a first electrode having a first plurality of fingers and a second electrode having a second plurality of fingers interdigitated with the first plurality of fingers of the first electrode.

26. The SAW device of claim 25, wherein the dielectric layer comprises aluminum oxide (Al₂O₃).

27. The SAW device of claim 25, wherein the dielectric layer has a relative permittivity greater than 3.9.

28. The SAW device of claim 25, wherein the dielectric layer has a relative permittivity of at least 9.3.

29. The SAW device of claim 25, wherein the dielectric layer is a continuous layer under the IDT.

30. The SAW device of claim 25, wherein the dielectric layer has a height of at least 2.5 nm.
